(19) United States
(12) Patent Application Publication
(10) Pub. No.: US 2025/0389528 A1
(43) Pub. Date: Dec. 25, 2025

(54) MAGNETOSTRICTIVE DISPLACEMENT SENSOR

(71) Applicant: Temposonics, LLC, Cary, NC (US)

(72) Inventors: Frank Kraehe, Morrisville, NC (US); Ian Lucas Young, Cary, NC (US)

(21) Appl. No.: 19/247,316

(22) Filed: Jun. 24, 2025

Related U.S. Application Data
(60) Provisional application No. 63/663,965, filed on Jun. 25, 2024.

(51) Int. Cl. G01B 7/02; G01B 7/24; G01D 5/48; G01R 33/18

(52) U.S. Cl. CPC G01B 7/02; G01B 7/24; G01D 5/485; G01R 33/18

(57) ABSTRACT

A magnetostrictive displacement sensor includes a sensor assembly having a printed circuit board (PCB), an anchor attached to the PCB, a waveguide having a first end attached to the anchor, and a sensing element. The sensing element includes a rigid member and a coil. The rigid member is attached to the waveguide and extends through an opening in the PCB and is configured to experience a strain in response to a magnetostrictive response in in the waveguide. The coil is attached to the PCB and surrounds the rigid member and the opening. The coil is configured to output a sensor signal that includes an indicator, which is produced in response to the strain in the rigid member.

### CROSS-REFERENCE TO RELATED APPLICATION(S)

The present application is based on and claims the benefit of U.S. provisional patent application Ser. No. 63/663,965, filed Jun. 25, 2024, the content of which is hereby incorporated by reference in its entirety.

### FIELD

Embodiments of the present disclosure generally relate to magnetostrictive displacement sensors, and more specifically, to a magnetostrictive displacement sensors that may be configured for installation into small housings.

### BACKGROUND

Magnetostrictive displacement sensors are robust, high resolution instruments which have proven to be useful in many measurement and control applications. Magnetostrictive displacement sensors generally include a sensor assembly, sensor electronics and a target magnet.

The sensor assembly generally includes a waveguide (e.g., conductive wire) and a pickup. The target magnet has a variable position along the waveguide corresponding to the position to be measured. The sensor electronics includes an excitation generator circuit that generates an excitation signal, such as a current pulse, which is conducted through the waveguide.

The excitation signal creates a magnetic field around the waveguide that interacts with the magnetic field of the target magnet to create a magnetostrictive response in the waveguide at the location of the target magnet. The magnetostrictive response takes the form of a sonic wave having mechanical pulse components including a longitudinal wave corresponding to a compression of the waveguide along its longitudinal axis, and a torsional wave corresponding to a torsional strain on the surface of the waveguide around the longitudinal axis.

The pickup is located at an end of the waveguide and includes a transducer or sensing element that is used to detect the longitudinal wave or torsional wave by converting the wave into an electrical sensor signal. The sensor signal may be processed, such as by the sensor electronics, to determine the position of the target magnet based on a time of flight measurement from the generation of the excitation signal and the detection of the longitudinal wave or the torsional wave.

The sensor signal generated by the sensing element is typically an extremely weak signal (e.g., _A) and is conducted at a high impedance. This makes the signal susceptible to noise and electromagnetic compatibility issues with the sensor electronics. As a result, conventional sensing element and sensor assembly designs focus on maximizing the signal-to-noise ratio of the sensor signal by maximizing the energy harvested by the sensing element and the amplitude of the sensor signal through optimization of physical parameters of the sensing element.

However, such optimization of the sensing element limits the minimum size of the sensing element. As a result, conventional magnetostrictive sensors have limited applications due to size constraints.

### SUMMARY

Embodiments of the present disclosure are generally directed to sensor assemblies, magnetostrictive displacement sensors including the sensor assemblies, and methods of operating a magnetostrictive displacement sensor.

One example of the magnetostrictive displacement sensor includes a sensor assembly having a printed circuit board (PCB), an anchor attached to the PCB, a waveguide having a first end attached to the anchor, and a sensing element. The sensing element includes a rigid member and a coil. The rigid member is attached to the waveguide, extends through an opening in the PCB and is configured to experience a strain in response to a magnetostrictive response in in the waveguide. The coil is attached to the PCB and surrounds the rigid member and the opening. The coil is configured to output a sensor signal that includes an indicator, which is produced in response to the strain in the rigid member.

Another example of the magnetostrictive displacement sensor includes a sensor assembly, an excitation generator, a target magnet and a controller. The sensor assembly includes a PCB, an anchor attached to the PCB, a waveguide having a first end attached to the anchor, and a sensing element. The sensing element includes a rigid member, which is attached to the waveguide, extends through an opening in the PCB and is configured to experience a strain in response to a magnetostrictive response in in the waveguide. The coil is attached to the PCB and surrounds the rigid member and the opening. The coil is configured to output a sensor signal that includes an indicator, which is produced in response to the strain in the rigid member. The excitation generator is configured to transmit current pulse through the waveguide. The target magnet has a moveable position along an axis of the waveguide. The magnetostrictive response is generated in the waveguide in response to an interaction between a magnetic field of the target magnet and a magnetic field of the current pulse. The controller is configured to calculate the position of the target magnet along the axis based on the indicator and generate a position output that indicates the position of the target magnet.

In an example of the method of operating a magnetostrictive displacement sensor, the magnetostrictive displacement sensor includes a sensor assembly, an excitation generator, a target magnet, and a controller. The sensor assembly includes a PCB, an anchor attached to the PCB, a waveguide having a first end attached to the anchor, and a sensing element. The sensing element includes a rigid member, which is attached to the waveguide and extends through an opening in the PCB, and a coil, which is attached to the PCB and surrounds the rigid member and the opening. The target magnet has a moveable position along an axis of the waveguide. In the method, a current signal is generated and transmitted through the waveguide using the excitation generator. A magnetostrictive response is generated in the waveguide in response to an interaction between a magnetic field of the target magnet and a magnetic field of the current signal. The rigid member is strained in response to the magnetostrictive response. A sensor signal is generated in the coil that includes an indicator, which is produced in response to straining the rigid member. The position of the target magnet along the axis is calculated based on the indicator, and a position output is generated that indicates the position of the target magnet using the controller.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter. The claimed subject matter is not limited to implementations that solve any or all disadvantages noted in the Background.

### BRIEF DESCRIPTION OF THE DRAWINGS

FIGS. 1 and 2 respectively are a schematic pictorial view and a simplified circuit diagram of an example of a magnetostrictive displacement sensor, in accordance with embodiments of the present disclosure.

FIG. 3 is a simplified isometric view of an example of a pickup, in accordance with embodiments of the present disclosure.

FIG. 4 is a simplified diagram of an example of a magnetostrictive displacement sensor, in accordance with embodiments of the present disclosure.

FIG. 5 is a simplified isometric view of an anchor supporting an end of a waveguide, in accordance with embodiments of the present disclosure.

FIG. 6 is a flowchart illustrating a method of operating a magnetostrictive displacement sensor, in accordance with embodiments of the present disclosure.

### DETAILED DESCRIPTION OF ILLUSTRATIVE EMBODIMENTS

Embodiments of the present disclosure are described more fully hereinafter with reference to the accompanying drawings. Elements that are identified using the same or similar reference characters refer to the same or similar elements. The various embodiments of the present disclosure may, however, be embodied in many different forms and should not be construed as limited to the specific embodiments set forth herein. Rather, embodiments are described so that this disclosure will be thorough and complete, and will fully convey the scope of the embodiments to those skilled in the relevant art.

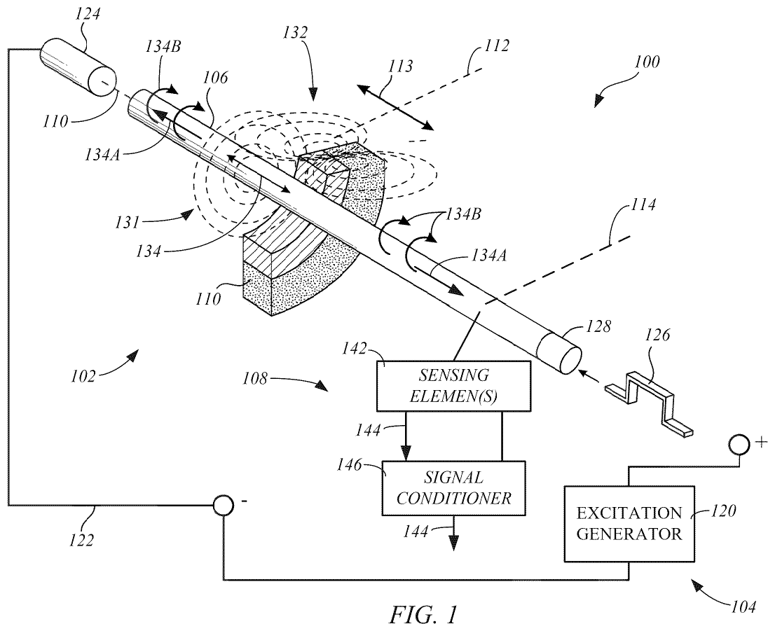

FIGS. 1 and 2 respectively are a schematic pictorial view and a simplified circuit diagram of an example of a magnetostrictive displacement sensor (MDS) 100, in accordance with embodiments of the present disclosure. The MDS 100 includes a sensor assembly 102 and sensor electronics 104. The sensor assembly 102 includes a conductor having magnetoclastic properties, referred to as a waveguide 106 and a pickup 108.

At least one target magnet 110 is located near the waveguide 106 and has a position 112 that is adjustable along an axis 111 of the waveguide 106, as indicated by arrow 113. The target magnet 110 may take the form of a bar magnet positioned alongside the waveguide 106, a ring magnet that surrounds the waveguide 106, or another suitable form. The MDS 100 is generally configured to measure the position 112 of the target magnet 110 along the waveguide 106 relative to a reference position 114.

The sensor electronics 104 includes a controller 116 having one or more processors 118, and an excitation generator circuit 120 that is connected to the waveguide 106. The one or more processors 118 are configured to perform functions described herein in response to the execution of program instructions stored in a non-transitory computer-readable medium, such as memory (e.g., flash memory, optical data storage, magnetic data storage, etc.) of the controller 116 or other suitable memory. In some embodiments, the processor(s) 118 of the controller 116 may comprise one or more computer-based systems, control circuits, microprocessor-based engine control systems, and/or programmable hardware components (e.g., field programmable gate array), for example.

A closed electrical circuit may be formed by the excitation generator circuit 120, the waveguide 106, and a return wire 122 that connects a distal end 124 of the waveguide 106 back to the excitation generator circuit 120, as shown in FIG. 1. The controller 116 uses the excitation generator circuit 120 to generate an excitation signal (e.g., electrical current pulse) 126 that is delivered to a proximal end 128 of the waveguide 106. An amplifier 130 (FIG. 2) of the sensor electronics 104 may be used to amplify the current pulse 126 before applying it to the waveguide 106.

The transmission of the current pulse 126 through the waveguide 106 generates a magnetic field 131 that interacts with the magnetic field 132 of the magnet 110 to generate a mechanical magnetostrictive response (e.g., acoustic waves) 134 in the waveguide 106, which includes a longitudinal wave 134A (e.g., longitudinal compression) and a torsional wave 134B (e.g., torsional strain), as indicated in FIG. 1.

The magnetostrictive response 134 travels from both sides of the magnet 110 along the waveguide 106. For example, a portion of the magnetostrictive response 134 may travel along the waveguide 106 from the position 112 of the magnet 110 toward the end 124 and possibly to a damper (not shown) that reduces or eliminates propagation of the acoustic waves 134 back through the waveguide 106. Additionally, a portion of the magnetostrictive response 134 travels from the position 112 of the magnet 110 toward the end 128, at which a magnetostrictive response pickup 108 is used to sense the magnetostrictive response 134, such as the longitudinal wave 134A and/or the torsional wave 134B.

The pickup 108 includes one or more transducers or sensing elements 142 that are configured generate an electrical sensor signal 144 that includes an indicator of the longitudinal wave 134A and/or an indicator of the torsional wave 134B. The one or more indicators may comprise a transient change or pulse in the magnitude of the signal 144, for example. The indicators may be detected by the controller 116 to determine the position 112 of the target magnet 110 based on the time from when the current pulse 126 is generated to when the indicator of the magnetostrictive response 134 is detected in the signal 144, in accordance with conventional techniques. The controller 116 may output a position estimate 145 that is indicative of the determined position 112 of the target magnet 110.

A signal conditioner 146 of the pickup 108 may be used to isolate the sensing element 142 from electrical interference and condition (e.g., amplify, rectify, filter, etc.) the signals 144 before delivering it to the sensor electronics 104, as indicated in FIG. 2. Thus, in some embodiments, the sensor signal 144 generated by the pickup 108 may be the original signal 144 generated by the sensing element(s) 142, such as when the pickup 108 does not include the signal conditioner 146, or the sensor signal 144 after processing by the circuitry of the signal conditioner 146.

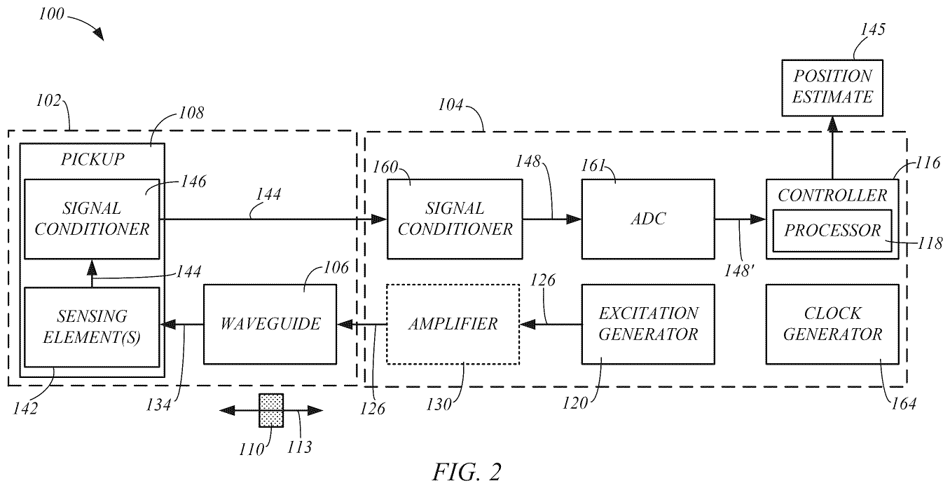

FIG. 3 is an isometric view of an example pickup 108 having a sensing element 142 that includes a coil 150 that is attached to the waveguide 106, such as through a rigid member or tape 152, as shown in FIG. 3. A bias magnet 154 is positioned near the coil 150 and produces a magnetic field that surrounds the coil 150. When the magnetostrictive response 134 (e.g., longitudinal wave or torsional wave) traveling through the waveguide 106 reaches the member 152, it generates a strain in the member 152 that causes a change in the magnetization of the member 152 in accordance with the Villari effect. The variable permeability of the member 152 in combination with the magnetic field of the bias magnet 154 results in a variation in the flux through the coil 150, which drives a current pulse indicator of the magnetostrictive response 134 in the sensor signal 144. As mentioned above, the sensor signal 144 from the coil 150 may be processed by a signal conditioner 146 prior to its delivery to the controller 116 (FIG. 2).

The pulse indicator portion of the sensor signal 144 representing the magnetostrictive response 134 is typically an extremely weak signal (e.g., 0.1 V) and is conducted at a high impedance. This makes the sensor signal 144 susceptible to noise and electromagnetic compatibility with the sensor electronics 104. Conventional forms of the sensing element 142 are optimized to maximize the signal-to-noise ratio of the sensor signal 144 by maximizing the amplitude or energy of the magnetostrictive response indicator in the sensor signal 144 that is harvested by the coil 150 through the optimization of certain parameters of the sensing element 142, such as the dimensions of the coil 150 and the member 152.

The sensing element 142 generally has a sensory space 158, through which the change in magnetic flux variation produced in response to the strain in the member 152 from the magnetostrictive response 134 generates the indicator in the sensor signal 144. A length 160 of the sensory space 158 is generally set to be around one-half the wavelength of the magnetostrictive response 134 in the waveguide 106 to maximize the energy harvested by the coil 150.

The length 160 of the sensory space 158 is equal to about a length 162 of the coil plus 20% of its outer diameter. Thus, the coil 150 of the sensing element is conventionally selected such that its length 162 and outer diameter form a sensory space 158 having an optimized length 160 that maximizes the energy harvested by the coil 150.

The number of turns of the coil 150 also affects the energy that may be harvested. The more turns of the coil 150, the greater the energy that can be harvested. Thus, conventional sensing elements 142 attempt to maximize the number of turns of the sensing element coil 150.

A length of the member 152 within the sensory space 158 also affects the energy that can be harvested by the coil 150. This length is conventionally set to one-half of the wavelength of the magnetostrictive response 134 or the length 160 of the sensory space 158 to take advantage of constructive interference and maximize the energy that can be harvested by the coil 150.

The securement of the proximal end 128 of the waveguide 106 and the placement of the member 152 relative to the proximal end 128 of the waveguide 106 are also used to promote a higher amplitude current pulse indicator of the magnetostrictive response in the sensor signal 144 by the pickup 108. For example, the proximal end 128 is conventionally strongly anchored in place in an effort to promote a strong reflection of the magnetostrictive response 134 at the end 128, such as by surrounding the end 128 with an epoxy that strongly secures the end 128 to a base material. Furthermore, the waveguide 106 itself is conventionally firmly fixed in place relative to the components of the pickup, such as using potting materials, to prevent movements of the waveguide 106 relative to the pickup 108 that could generate undesired noise in the sensor signal 144. Additionally, the member 152 is conventionally positioned one-half of a wavelength of the magnetostrictive response 134 from the end 128 to promote constructive interference of the magnetostrictive response 134 at the member 152.

In one example, a torsional wave magnetostrictive pulse 134B (FIG. 1) in a typical waveguide 106 (e.g., formed of nickel) travels at approximately 2800 meters/second (m/s), has a frequency of about 250-300 kHz and a wavelength of approximately 1.0-1.1 cm. Thus, when such a torsional wave 134B is targeted by the sensing element, the length 160 of the sensory space 158 is set to about 5.0-5.5 mm, and the length of the member 152 within the sensory space 158 is set to about 5.0-5.5 mm. Additionally, the coil 150 of the sensing element 142 will have a length and diameter that results in the desired sensory space length 160, and have about 1800 turns to maximize the amplitude of the magnetostrictive response indicators in the senor signal 144.

Conventional sensing elements 142 also include magnetic and electrical shielding to reduce the sensitivity of the sensing element 142 to magnetic and electromagnetic interference and further optimize the performance of the sensing element 142. Such shielding further expands the size of the sensing element 142 and the resultant sensor assembly 108 and magnetostrictive displacement sensor.

While the optimization of the sensing element 142 is preferred to maximize the amplitude and signal-to-noise ratio of magnetostrictive response indicators in the sensor signal 144, such optimization also places limits on the minimum size of the sensing element 142. As a result, the applications for conventional sensor assemblies 108 are generally limited due to size constraints.

Embodiments of the present disclosure are directed to magnetostrictive displacement sensor pickups 108 comprising a unique sensing element 142 that may be formed smaller than conventional sensing elements. This allows the sensor assembly using the pickup 142 to be installed into smaller housings than would be possible for sensor assemblies having the conventional optimized pickup. Additional embodiments relate to sensor assemblies 108, magnetostrictive displacement sensors 100 that include the pickup 142 and methods of operating a magnetostrictive displacement sensor 100 comprising the pickup 142.

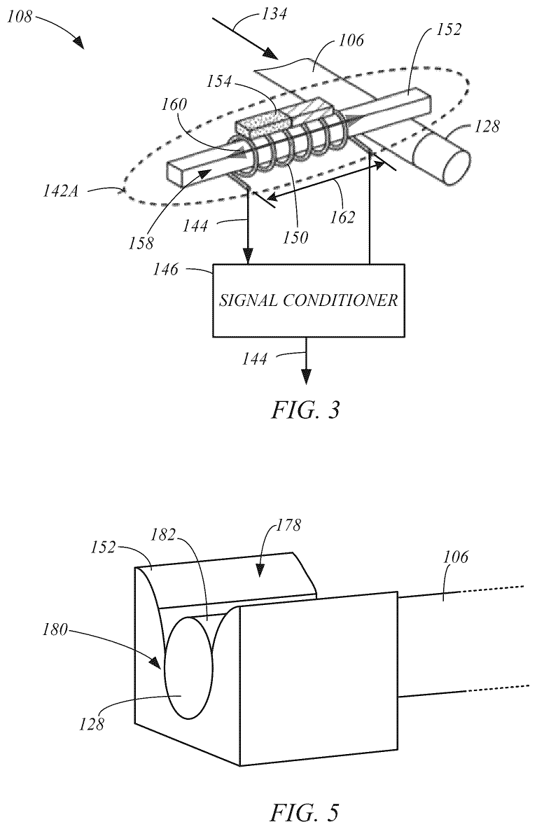

FIG. 4 is a simplified diagram of an example of an MDS 100, in accordance with embodiments of the present disclosure. The sensor 100 includes a sensor assembly 108 and sensor electronics 104. The sensor electronics 104 may be formed in accordance with one or more embodiments described herein to generate the current pulse 126 using the excitation generator 120 and process the sensor signal 144 to produce the position estimate 145 that is indicative of the location 112 of a target magnet 110 along the axis 111 of the waveguide 106, as discussed above. The system electronics 104 may comprise a printed circuit board (PCB) 170 that facilitates electrical connections between the processor(s) 118 of the controller 116 and other components, for example. Thus, the PCB 170 may include all or a portion of the sensor electronics 104.

In some embodiments, the sensor assembly 108 includes a portion of the PCB 170 of the sensor electronics 104, as indicated in FIG. 4, or a separate PCB, an anchor 172, a pickup 142 and a waveguide 106. The waveguide 106 may take the form of a conventional waveguide 106 wire formed of nickel, a nickel-iron alloy, a cobalt-iron alloy, or another suitable magnetostrictive material. The proximal end 128 of the waveguide 106 is connected to the anchor 172, which is attached to the PCB 170, such as to a surface 174 of the PCB 170. A return conductor or wire 122 connects the distal end 124 of the waveguide 106 to the sensor electronics 104. In one embodiment, the return wire 122 includes a conductive trace 174 within a layer of the PCB 170, and may include an additional conductor 176 between the conductive trace 174 and the end 124 of the waveguide 106. The waveguide 106 is configured to receive the current pulse 126 from the excitation generator 120 (FIGS. 1 and 2), which is conducted through the waveguide 106 and returned to the sensor electronics 104 through the conductive trace 174 of the PCB 170.

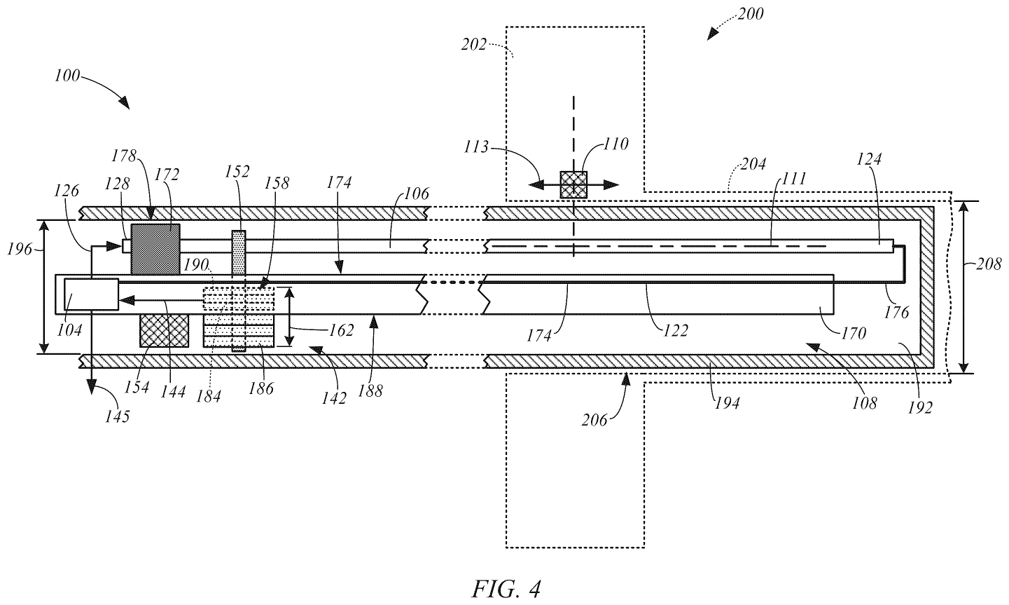

The anchor 172 may take on any suitable form. FIG. 5 is a simplified isometric view of an example of the anchor 172, in accordance with embodiments of the present disclosure. Connections to the waveguide end 128 for supplying the current pulse 126 and other components are not shown in order to simplify the drawing. In one embodiment, the anchor 172 includes an open top 178, through which the proximal end 128 of the waveguide 106 is received into a socket or constrictive portion 180 that pinches and secures the end 128 to the anchor 172 and the PCB 170. The constrictive portion 180 may be formed of Phosphor Bronze and may flex slightly to receive the waveguide end 128 as it is press-fit through the opening 178 into constrictive portion 180, such as by hand. In some embodiments, a top portion 182 of the waveguide end 128 within the anchor 172 is left exposed through the opening 178, such that the anchor 172 does not completely surround the end 128. Additionally, the waveguide portion 182 may be left exposed, such as by not covering the portion 182 with an epoxy, potting, or other material.

This technique of securing the proximal end 128 of the waveguide 106 is distinguishable from conventional techniques. For example, embodiments of the anchor 172 do not secure the waveguide end 128 as strongly as conventional techniques that completely surround the end 128, such as using an epoxy. As a result, when the waveguide end 128 is secured using the anchor 172, the reflection of the magnetostrictive response 134 at the end 128 is not as strong as it would be when conventional anchoring techniques are used.

In some embodiments, the distal end 124 of the waveguide 106 is only attached to the PCB 170 through the return wire 122, such as the conductor 176. Accordingly, an intermediary portion of the waveguide 106 between the anchor 172 and the distal end 124 is detached from the PCB 170. That is, the intermediary portion is not directly connected to the PCB 170. As a result, the waveguide 106 may be subject to movement relative to the PCB 170 and the pickup 142, that can adversely affect the signal-to-noise ratio of the sensor signal 144 generated by the pickup 142.

The rigid member 152 may be attached to the waveguide 106 near the end 128, such as at one-half of a wavelength of the magnetostrictive response 134 from the end 128. The member 152 extends from the waveguide 106 toward the PCB 170 and through an opening 184 in the PCB 170, as indicated in FIG. 4.

The coil 150 is formed by a conductor having a number of turns that surround a portion of the member 152, such as over a length 162 of the coil 150. The conductor forming the coil 150 may include turns 186 that are attached to the PCB 170, such as at a surface 188, and/or the conductor may include turns formed by traces 190 within one or more layers of the PCB 170, as indicated in FIG. 4.

In some embodiments, parameters of the pickup 142 may be sub-optimal relative to a conventional pickup. As a result, the sensor signal 144 produced by the pickup 142 includes magnetostrictive response indicators having a lower signal-to-noise ratio than that produced by conventional sensor assemblies having more optimal pickups. However, many of these sub-optimal features allow the pickup 142 and sensor assembly 108 to be formed more compactly than conventional sensor assemblies, thereby facilitating new applications for the MDS 100 using the sub-optimal pickup 142.

In one example, the sensory space 158 (FIG. 3) of the pickup 142 or coil 150 is reduced compared to conventional optimized pickups. In some embodiments, the length of the sensory space 158 is reduced by about 15-50% less than one-half a wavelength of the magnetostrictive response 134 in the waveguide 106 and the optimized sensory space length. Thus, when the wavelength of the magnetostrictive response 134 is about 1.0 cm, the length of the sensory space may be about 2.5-4.0 mm, such as about 3.1 mm, while the optimal length of the sensory space 158 is about 5.0 mm. Accordingly, embodiments of the coil 150 having a length 162 that is similar to the sub-optimal length of the sensory space 158, such as about of the coil may have a similar length to this sensory space of about 15-50% less than one-half a wavelength of the magnetostrictive response 134 in the waveguide 106, or about 2.5-4.0 mm, such as about 3.1 mm.

In some embodiments, the length of the member 152 within the sensory space 158 generally corresponds to the length of the sensory space 158. Thus, examples of the length of the member 152 within the sensory space 158 is about 15-50% less than one-half a wavelength of the magnetostrictive response 134 in the waveguide 106. Accordingly, when the wavelength of the magnetostrictive response 134 is about 1.0 cm, the length of the member 152 within the sensory space 158 may be about 2.5-4.0 mm, such as about 3.1 mm, while the optimal length of the member 152 within the sensory space 158 is about 5.0 mm.

In some embodiments, the size of the coil 150 is also reduced through a reduction in the number of coil turns. For example, the coil 150 may comprise less than about 1400 turns, such as about 800-1200 or around 1020 turns. This is significantly less than conventional pickups whose coils have about 1800 turns, for example.

Some embodiments of the sensing element 142 are further reduced in size by eliminating conventional shielding for magnetic and/or electrical interference.

By reducing the size of the sensing element 142 through a reduction in the size of the coil 150 and/or the member 152, the sensing element 142, and magnetostrictive displacement sensors 150 or sensor assemblies 108 utilizing the sensing element 142, may be formed more compactly than their conventional counterparts. As a result, embodiments of the sensing element 142 may be utilized in applications that would not be possible using conventional, larger sensing elements. The reduced signal-to-noise ratio of the indicators in the sensor signal 144 that are produced by the sub-optimal sensing element may be detected by the controller 116, such as using the techniques disclosed in U.S. Pat. No. 11,543,269, which is incorporated herein by reference in its entirety.

Additional embodiments of the present disclosure relate to example uses of the MDS 100, which may take advantage of its ability to be used in smaller spaces than conventional magnetostrictive displacement sensors. In one example, the MDS 100 may be installed within an interior cavity 192 of a housing 194, such as a pipe or rod, as shown in FIG. 5. The interior cavity 192 of the housing 194 may have a small internal diameter 196, such as about 7 mm, that can accommodate the MDS 100, while conventional sensors generally require an internal diameter of 25 mm or more to accommodate their larger sized sensing elements.

In one example, the MDS 100 may be used in combination with a piston assembly 200 comprising a piston 202 and a piston rod 204 having a central bore 206 having an internal diameter 208 that is configured to receive the housing 194, as indicated in phantom lines in FIG. 4. The target magnet 110 may be attached to the piston 202 and used to establish a location 112 of the piston 202 relative to the waveguide 106. Such an arrangement may be used in hydraulic actuators or struts, for example.

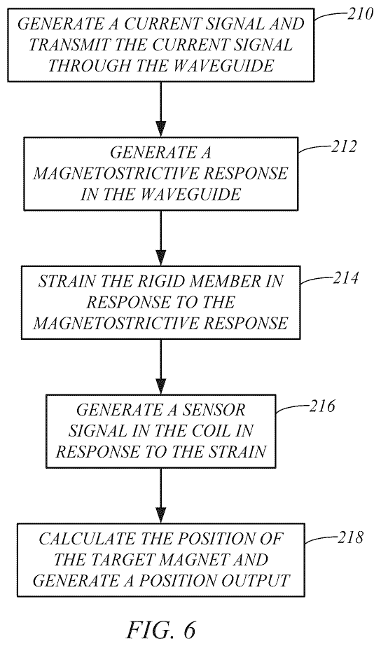

FIG. 6 is a flowchart illustrating a method of operating the MDS 100, in accordance with embodiments of the present disclosure. In some embodiments, the MDS 100 is formed in accordance with one or more embodiments described above, such as those shown in FIG. 4. Thus, the MDS 100 may comprise a sensor assembly 108 that includes the PCB 170, the anchor 172, the waveguide 106 and the pickup 142, in accordance with one or more embodiments described herein. The MDS 100 may also include the sensor electronics 104 comprising the excitation generator 120 and the controller 116, in accordance with one or more embodiments described herein.

At 210 of the method, a current signal 136 is generated and transmitted through the waveguide 106 using the excitation generator 120. A magnetostrictive response 134 is generated in the waveguide 106 at 212 in response to an interaction between a magnetic field 132 of a target magnet 110 and a magnetic field 131 of the excitation signal 126. At 214, the member 152 is strained in response to the magnetostrictive response 134, and a sensor signal 144 is generated in the coil 150 in response to the strain of the member at 216. Finally, at 218, a position 112 of the target magnet 110 along the axis 111 of the waveguide is calculated or determined based on the sensor signal 144 and a position output 145 is generated that indicates the position 112 using the controller 116.

Although the embodiments of the present disclosure have been described with reference to preferred embodiments, workers skilled in the art will recognize that changes may be made in form and detail without departing from the spirit and scope of the present disclosure.

Functions recited herein may be performed by a single controller or processor, multiple controllers or processors, or at least one controller or processor. As used herein, when one or more functions are described as being performed by a controller (e.g., a specific controller), one or more controllers, at least one controller, a processor (e.g., such as a specific processor), one or more processors or at least one processor, embodiments include the performance of the function(s) by a single controller or processor, or multiple controllers or processors, such as in response to the execution of program instructions stored in a non-transitory computer-readable medium, unless otherwise specified. Furthermore, as used herein, when multiple functions are performed by at least one controller or processor, all of the functions may be performed by a single controller or processor, or some functions may be performed by one controller or one processor, and other functions may be performed by another controller or processor. Thus, the performance of one or more functions by at least one controller or processor does not require that all of the functions are performed by each of the controllers or processors, or by a single one of the controllers or processors.

What is claimed is:

1. A magnetostrictive displacement sensor including a sensor assembly comprising:
a printed circuit board (PCB);
an anchor attached to the PCB;
a waveguide having a first end attached to the anchor; and
a sensing element comprising:
a rigid member attached to the waveguide and extending through an opening in the PCB and configured to experience a strain in response to a magnetostrictive response in in the waveguide; and
a coil attached to the PCB and surrounding the rigid member and the opening, the coil configured to output a sensor signal that includes an indicator, which is produced in response to the strain in the rigid member.

2. The sensor according to claim 1, wherein a length of the coil is about 15-50% less than one-half a wavelength of the magnetostrictive response in the waveguide.

3. The sensor according to claim 2, wherein a length of the coil is about 2.5-4.0 mm.

4. The sensor according to claim 3, wherein the coil comprises a conductor that is attached to the PCB and/or a conductor formed by traces in the PCB.

5. The sensor according to claim 4, wherein the coil comprises less than about 1400 turns.

6. The sensor according to claim 2, wherein a length of the rigid member is about 15-50% less than one-half a wavelength of the magnetostrictive response in the waveguide.

7. The sensor according to claim 1, wherein the sensing element comprises a bias magnet attached to the PCB.

8. The sensor according to claim 1, wherein the anchor comprises an open top through which the first end of the waveguide is received.

9. The sensor according to claim 8, wherein the anchor pinches the first end of the waveguide.

10. The sensor according to claim 9, wherein the anchor does not surround the first end of the waveguide.

11. The sensor according to claim 1, wherein:
the sensor includes a housing containing the sensor assembly;
the waveguide includes a second end that is attached to the PCB; and
an intermediary portion of the waveguide extending between the first and second ends is detached from the PCB.

12. The sensor according to claim 1, including:
an excitation generator configured to transmit a current pulse through the waveguide;
a target magnet having a moveable position along an axis of the waveguide, wherein the magnetostrictive response is generated in the waveguide in response to an interaction between a magnetic field of the target magnet and a magnetic field of the current pulse; and
a controller configured to calculate the position of the target magnet along the axis based on the indicator and generate a position output that indicates the position of the target magnet.

13. A magnetostrictive displacement sensor including:
a sensor assembly comprising:
a printed circuit board (PCB);
an anchor attached to the PCB;
a waveguide having a first end attached to the anchor; and
a sensing element comprising:
a rigid member attached to the waveguide and extending through an opening in the PCB and configured to experience a strain in response to a magnetostrictive response in in the waveguide; and
a coil attached to the PCB and surrounding the rigid member and the opening, the coil configured to output a sensor signal that includes an indicator, which is produced in response to the strain in the rigid member;
an excitation generator configured to transmit current pulse through the waveguide;
a target magnet having a moveable position along an axis of the waveguide, wherein the magnetostrictive response is generated in the waveguide in response to an interaction between a magnetic field of the target magnet and a magnetic field of the current pulse; and
a controller configured to calculate the position of the target magnet along the axis based on the indicator and generate a position output that indicates the position of the target magnet.

14. The sensor according to claim 13, wherein:
the coil comprises a conductor that is attached to the PCT and/or a conductor formed by traces in the PCB;
a length of the coil is about 15-50% less than one-half a wavelength of the magnetostrictive response in the waveguide;
a length of the coil is about 2.5-4 mm; and/or
the coil comprises less than about 1400 turns.

15. The sensor according to claim 14, wherein a length of the rigid member is about 15-50% less than one-half a wavelength of the magnetostrictive response in the waveguide.

16. The sensor according to claim 14, wherein the sensing element comprises a bias magnet attached to the PCB.

17. The sensor according to claim 13, wherein:
the anchor comprises an open top through which the first end of the waveguide is received;
the anchor pinches the first end of the waveguide; and/or
the anchor does not surround the first end of the waveguide.

18. The sensor according to claim 13, wherein:
the sensor includes a housing containing the sensor assembly; and
the waveguide includes a second end that is attached to the PCB; and
an intermediary portion of the waveguide extending between the first and second ends is detached from the PCB.

19. A method of operating a magnetostrictive displacement sensor, which includes:
a sensor assembly comprising:
a printed circuit board (PCB);
an anchor attached to the PCB;
a waveguide having a first end attached to the anchor; and
a sensing element comprising:
a rigid member attached to the waveguide and extending through an opening in the PCB; and
a coil attached to the PCB and surrounding the rigid member and the opening;
an excitation generator;
a target magnet having a moveable position along an axis of the waveguide; and
a controller,
the method comprising:
generating a current signal and transmitting the current signal through the waveguide using the excitation generator;
generating a magnetostrictive response in the waveguide in response to an interaction between a magnetic field of the target magnet and a magnetic field of the current signal;
straining the rigid member in response to the magnetostrictive response;
generating a sensor signal in the coil that includes an indicator, which is produced in response to straining the rigid member; and
calculating the position of the target magnet along the axis based on the indicator and generating a position output that indicates the position of the target magnet using the controller.

20. The method according to claim 19, wherein:
the coil comprises a conductor that is attached to the PCT and/or a conductor formed by traces in the PCB;
a length of the coil is about 15-50% less than one-half a wavelength of the magnetostrictive response in the waveguide;
a length of the coil is about 2.5-4 mm;
the coil comprises less than about 1400 turns;
a length of the rigid member is about 15-50% less than one-half the wavelength;
the sensing element comprises a bias magnet attached to the PCB; and/or
the anchor comprises an open top through which the first end of the waveguide is received.
